(19) United States
(12) Patent Application Publication
(10) Pub. No.: US 2022/0020951 A1
(43) Pub. Date: Jan. 20, 2022

(54) GRADED SLOPE REFLECTIVE STRUCTURES FOR OLED DISPLAY PIXELS

(71) Applicant: Applied Materials, Inc., Santa Clara, CA (US)

(72) Inventors: Chung-Chia CHEN, Hsinchu City (TW); Wan-Yu LIN, Taipei (TW); Gang YU, Santa Barbara, CA (US); Byung-Sung KWAK, Mountain View, CA (US); Robert Jan VISSER, Menlo Park, CA (US); Hyunsung BANG, Alzenau (DE); Lisong XU, Santa Clara, CA (US); Chung-Chih WU, Taipei City (TW); Hoang Yan LIN, Keelung City (TW); Guo-Dong SU, Taipei City (TW); YI-Jiun CHEN, Taipei (TW); Wei-Kai LEE, Taipei City (TW)

(21) Appl. No.: 17/373,939

(22) Filed: Jul. 13, 2021

(30) Foreign Application Priority Data
Jul. 16, 2020 (US) PCT/US2020/042244

(51) Int. Cl. H01L 51/52; G09G 3/3225; H01L 27/32; H01L 51/00; H01L 51/56

(52) U.S. Cl. CPC H01L 51/5218; G09G 3/3225; H01L 27/3246; H01L 51/5209; H01L 2227/323; H01L 51/56; H01L 2251/5315; H01L 2251/5346; H01L 51/0018

(57) ABSTRACT

Embodiments described herein relate to graded slope bottom reflective electrode layer structures for top-emitting organic light-emitting diode (OLED) display pixels. An EL device includes a pixel definition layer having a top surface, a bottom surface, and graded sidewalls interconnecting the top and bottom surfaces and a bottom reflective electrode layer disposed over the pixel definition layer. The bottom reflective electrode layer includes a planar electrode portion disposed over the bottom surface and a graded reflective portion disposed over the graded sidewalls, where the graded reflective portion has a concave profile. The EL device includes an organic layer disposed over the bottom reflective electrode layer and a top electrode disposed over the organic layer. Also described herein are methods for fabricating the EL device.

### CROSS-REFERENCE TO RELATED APPLICATIONS

This application claims benefit of PCT Application Serial No. PCT/US20/42244, filed on Jul. 16, 2020, the entirety of which is herein incorporated by reference.

### BACKGROUND

### Field

Embodiments of the present disclosure generally relate to electroluminescent (EL) devices with improved outcoupling efficiency. More specifically, embodiments described herein relate to graded slope bottom reflective electrode layer structures for organic light-emitting diode (OLED) display pixels.

### Description of the Related Art

Organic light-emitting diode (OLED) technologies have become an important next-generation display technology offering many advantages (e.g., high efficiency, wide viewing angles, fast response, and potentially low cost). In addition, as a result of improved efficiency, OLEDs are also becoming practical for some lighting applications. Even so, typical OLEDs still exhibit significant efficiency loss between internal quantum efficiency (IQE) and external quantum efficiency (EQE).

Through certain combinations of electrode materials, carrier-transport layers, e.g., hole-transport layers (HTLs) and electron-transport layers (ETLs), emission layers (EMLs), and layer stacking, IQE levels can reach nearly 100%. However, EQE levels of typical OLED structures remain limited by optical outcoupling inefficiencies. Outcoupling efficiencies can suffer from optical energy loss due to significant emitting light being trapped by total internal reflection (TIR) inside the OLED display pixels.

Typical top-emitting OLED structures include a substrate, a reflective electrode over the substrate, organic layer(s) over the reflective electrode, and a transparent or semi-transparent top electrode over the organic layer(s). Due to higher refractive indices of the organic layer(s) (typically n>=1.7) and top electrode (typically n>=1.8) relative to air (n=1), significant emitting light is confined by TIR at the device-air interface preventing outcoupling to air.

Also in typical OLED structures, a significant portion of waveguided light diffusing to neighboring pixels (i.e., light leakage) can be scattered in the viewing direction along with the outcoupled light from the respective pixels causing pixel blurring, thereby reducing display sharpness and contrast.

Accordingly, what is needed in the art are improved structures, namely improved reflective structures, for OLED display pixels and methods of fabrication thereof.

### SUMMARY

In one embodiment, an electroluminescent (EL) device is provided. The EL device includes a pixel definition layer having a top surface, a bottom surface, and graded sidewalls interconnecting the top and bottom surfaces and a bottom reflective electrode layer disposed over the pixel definition layer. The bottom reflective electrode layer includes a planar portion disposed over the bottom surface and a graded portion disposed over the graded sidewalls, where the graded portion has a concave profile. The EL device includes an organic layer disposed over the bottom reflective electrode layer and a top electrode disposed over the organic layer.

In another embodiment, a method for fabricating an EL device is provided. The method includes coating a pixel definition layer over a substrate, the pixel definition layer having a bottom surface facing the substrate and a top surface opposite the bottom surface, recessing the top surface to form graded sidewalls interconnecting the top and bottom surfaces, and forming a bottom reflective electrode layer in the recess. The bottom reflective electrode layer includes a planar portion disposed over the bottom surface and a graded portion disposed over the graded sidewalls, where the graded portion has a non-linear profile. The method includes forming an organic layer over the bottom reflective electrode layer and forming a top electrode over the organic layer.

In yet another embodiment, a display structure is provided. The display structure includes an array of EL devices. Each EL device includes a pixel definition layer having a top surface, a bottom surface, and graded sidewalls interconnecting the top and bottom surfaces and a bottom reflective electrode layer disposed over the pixel definition layer. The bottom reflective electrode layer includes a planar portion disposed over the bottom surface and a graded portion disposed over the graded sidewalls, where the graded portion has a concave profile. Each EL device includes an organic layer disposed over the bottom reflective electrode layer and a top electrode disposed over the organic layer. The display structure includes a plurality of thin-film transistors forming a driving circuit array configured to drive and control the array of EL devices and a plurality of interconnection layers. Each interconnection layer is in electrical contact between an EL device and a respective thin-film transistor of the plurality of thin-film transistors.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, top view of an array of electroluminescent (EL) devices, according to an embodiment.

FIG. 1B is a schematic, side view of the array of EL devices of FIG. 1A, according to an embodiment.

FIG. 1C is a schematic, side sectional view of an individual EL device taken along section line 1-1 of FIG. 1A, according to an embodiment.

FIG. 1D is a schematic, side sectional view of an individual EL device taken along section line 1-1 of FIG. 1A, according to another embodiment.

FIG. 2A is a schematic, side sectional view of a bottom reflective electrode layer having a convex graded slope which may be substituted for the bottom reflective electrode layer in the EL device of FIGS. 1C-1D, according to an embodiment.

FIG. 2B is a schematic, side sectional view of a bottom reflective electrode layer having a convex graded slope which may be substituted for the bottom reflective electrode layer in the EL device of FIGS. 1C-1D, according to another embodiment.

FIG. 3A is a schematic, side sectional view of a bottom reflective electrode layer having a concave graded slope which may be substituted for the bottom reflective electrode layer in the EL device of FIGS. 1C-1D, according to an embodiment.

FIG. 3B is a schematic, side sectional view of a bottom reflective electrode layer having a concave graded slope which may be substituted for the bottom reflective electrode layer in the EL device of FIGS. 1C-1D, according to another embodiment.

FIG. 4 is a schematic, side sectional view of a bottom reflective electrode layer having a graded slope which may be substituted for the bottom reflective electrode layer in the EL device of FIGS. 1C-1D, according to another embodiment.

FIG. 5 is a diagram illustrating a method for fabricating an EL device, according to an embodiment.

FIGS. 6A-6H are schematic, side sectional views of an EL device illustrating various aspects of the method set forth in FIG. 5, according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein relate to graded slope bottom reflective electrode layer structures for organic light-emitting diode (OLED) display pixels. An EL device includes a pixel definition layer having a top surface, a bottom surface, and graded sidewalls interconnecting the top and bottom surfaces and a bottom reflective electrode layer disposed over the pixel definition layer. The bottom reflective electrode layer includes a planar portion disposed over the bottom surface and a graded portion disposed over the graded sidewalls, where the graded portion has a non-linear profile. The EL device includes an organic layer disposed over the bottom reflective electrode layer and a top electrode disposed over the organic layer. Also described herein are methods for fabricating the EL device.

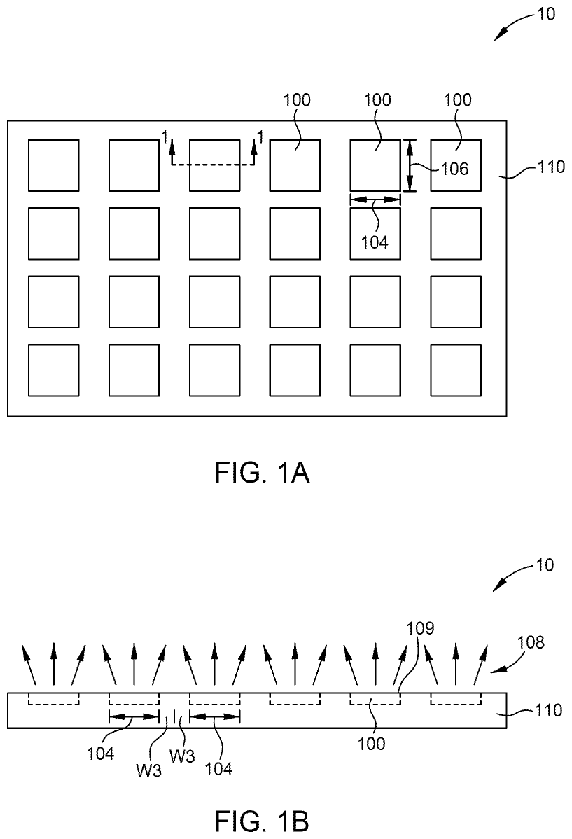

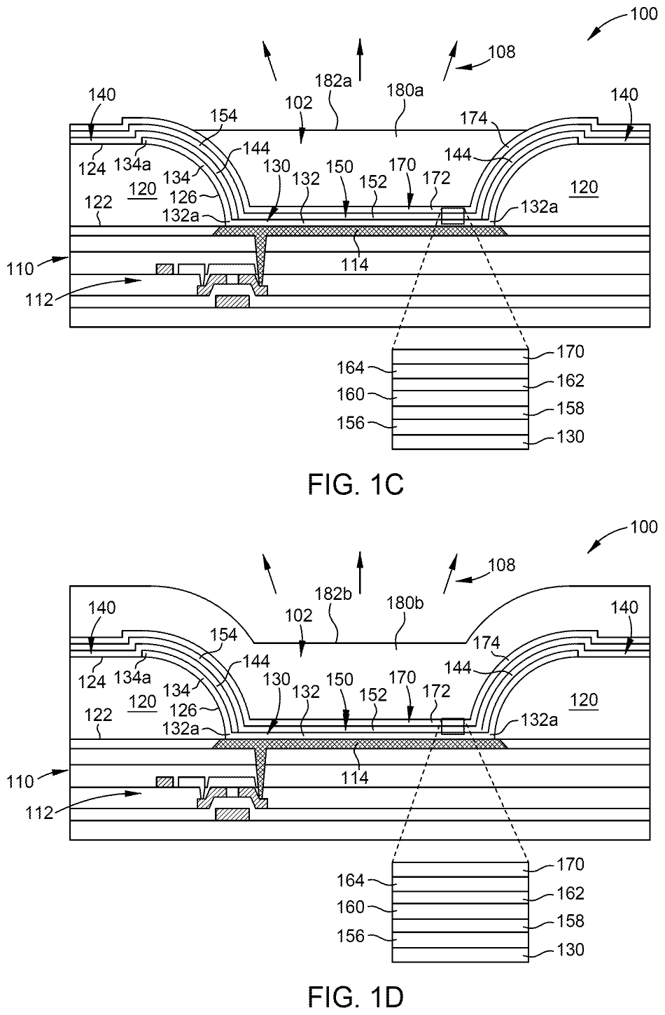

FIG. 1A is a schematic, top view of an array 10 of electroluminescent (EL) devices 100, according to an embodiment. The array 10 is formed on a substrate 110. In certain embodiments, the EL devices 100 may be OLED display pixels, and the array 10 may be a top-emitting active matrix OLED display (top-emitting AMOLED) structure. In some examples, a width 104 and a length 106 of the EL devices 100 may be from about 20 μm or less up to about 100 μm.

FIG. 1B is a schematic, side view of the array 10 of EL devices 100 of FIG. 1A, according to an embodiment. Here, the EL devices 100 (shown in phantom) are top-emitting and outcoupled light 108 exits the EL devices 100 from a top 109 thereof.

FIG. 1C is a schematic, side sectional view of an individual EL device 100 taken along section line 1-1 of FIG. 1A, according to an embodiment. FIG. 1D is a schematic, side sectional view of an individual EL device 100 taken along section line 1-1 of FIG. 1A, according to another embodiment. The EL device 100 generally includes the substrate 110, a pixel definition layer (PDL) 120, a bottom reflective electrode layer 130, a dielectric layer 140, an organic layer 150, where the organic layer 150 is a multi-layer stack including a plurality of organic layers, a top electrode 170, and a filler 180a, b. In some embodiments, the substrate 110 may be formed from one or more of a silicon, glass, quartz, plastic, or metal foil material. In some embodiments, the substrate 110 may include a plurality of device layers (e.g., buffer layers, interlayer dielectric layers, insulating layers, active layers, and electrode layers). Here, a thin-film transistor (TFT) 112 is formed on the substrate 110. In some embodiments, an array of TFTs 112 may form a TFT driving circuit array configured to drive and control the array 10 of EL devices 100. In some embodiments, the array 10 of EL devices 100 may be an OLED pixel array for a display. Here, an interconnection layer 114 is in electrical contact between the TFT 112 and the bottom reflective electrode layer 130. The EL device 100 electrically contacts the interconnection layer 114 via the bottom reflective electrode layer 130. In some embodiments, the EL device 100 includes a planarization layer (not shown) formed over the substrate 110.

The PDL 120 is disposed over the substrate 110. In some embodiments, a bottom surface 122 of the PDL 120 contacts the substrate 110, the interconnection layer 114, or both. The PDL 120 has a top surface 124 facing away from the substrate 110. An emission region 102 of the EL device 100 is formed by openings in the PDL 120 extending from the top surface 124 through to the bottom surface 122 of the PDL 120. The PDL 120 has graded sidewalls 126 (i.e., a graded bank) interconnecting the top and bottom surfaces 124, 122. Herein, graded is defined as being simple or compound curved. In some embodiments, the graded sidewalls 126 may have any non-linear profile. In some embodiments, the PDL 120 may be a photoresist formed from any suitable photosensitive organic or polymer-containing material. In some other embodiments, the PDL 120 may be formed from SiO₂, SiNₓ, SiON, SiCON, SiCN, Al₂O₃, TiO₂, Ta₂O₅, HfO₂, ZrO₂, or another dielectric material.

The bottom reflective electrode layer 130 (e.g., anode in standard OLED configuration) includes a planar electrode portion 132 disposed over the interconnection layer 114 and a graded reflective portion 134 disposed over the graded sidewalls 126 of the PDL 120. Here, the graded portion 134 connects to the opposed lateral ends 132a of the planar portion 132. In some embodiments, the bottom reflective electrode layer 130 may be conformal to the interconnection layer 114 and the graded sidewalls 126. In some embodiments, the bottom reflective electrode layer 130 may extend to the top surface 124 of the PDL 120. In some embodiments, the bottom reflective electrode layer 130 may be a monolayer. In some other embodiments, the bottom reflective electrode layer 130 may be a multi-layer stack. In some embodiments, the bottom reflective electrode layer 130 may include a transparent conductive oxide layer and a metal reflective film. In some embodiments, the transparent conductive oxide layer may include one or more of indium tin oxide (ITO), indium zinc oxide (IZO), zinc oxide (ZnO), indium oxide (In₂O₃), indium gallium oxide (IGO), aluminum zinc oxide (AZO), gallium zinc oxide (GZO), combinations thereof, and multi-layer stacks thereof. In some embodiments, the metal reflective film may include one or more of aluminum (Al), silver (Ag), magnesium (Mg), platinum (Pt), lead (Pd), gold (Au), nickel (Ni), neodymium (Nd), iridium (Ir), chromium (Cr), Al:Ag alloys, other alloys thereof, other suitable metals and their alloys, combinations thereof, and multi-layer stacks thereof. In some other embodiments, the bottom reflective electrode layer 130 may include a transparent conductive oxide layer and a Distributed Bragg Reflector (DBR) including alternately stacked high refractive index and low refractive index material layers forming a reflective multi-layer. In yet other embodiments, the transparent conductive oxide may be combined with one or more of a metal, transparent conductive metal oxide, transparent dielectric, scattering reflector, DBR, other suitable material layers, combinations thereof, and multi-layer stacks thereof.

In some embodiments, the bottom reflective electrode layer 130 may directly contact the interconnection layer 114 and the PDL 120. Here, the planar electrode portion 132 and the graded reflective portion 134 are formed of the same material. In some other embodiments, the interconnection layer 114 forms the planar electrode portion 132 of the bottom reflective electrode layer 130. In such embodiments, the planar electrode portion 132 and the graded reflective portion 134 may be formed from different materials. For example, the planar electrode portion 132 may be a multi-layer stack of ITO/Ag/ITO, and the graded reflective portion 134 may be a scattering reflector, DBR, or metal alloy.

One advantage of the bottom reflective electrode layer 130 having the graded bank structure is that the curved slope of the graded portion 134 is easier to fabricate compared to an analogous straight bank structure having a constant slope. In some aspects, the graded slope of the bottom reflective electrode layer 130 is analogous to a composition of straight bank structures having different slopes at different positions. In that regard, another advantage of the graded bank structure is averaging of redirection effects of different bank angles producing a more uniform emission pattern. Another advantage of the graded bank structure is that, relative to the straight bank structure, the graded slope produces angular intensities closer to the Lambertian distribution.

The dielectric layer 140 includes a graded portion 144 disposed over the graded portion 134 of the bottom reflective electrode layer 130. Here, the dielectric layer 140 terminates at the planar portion 132 of the bottom reflective electrode layer 130 without extending over the planar portion 132. In some other embodiments, the dielectric layer 140 may overlap the opposed lateral ends 132a of the planar portion 132 without extending over the entire planar portion 132. In some embodiments, the dielectric layer 140 may extend laterally beyond the graded portion 134 of the bottom reflective electrode layer 130 to the top surface 124 of the PDL 120. In some embodiments, the dielectric layer 140 may directly contact the bottom reflective electrode layer 130 and/or the PDL 120. In some embodiments, the dielectric layer 140 may be conformal to the bottom reflective electrode layer 130 and/or the PDL 120. In some embodiments, the dielectric layer 140 may include any suitable low-k dielectric material. In some embodiments, the dielectric layer 140 may be formed from SiO₂, SiNₓ, SiON, SiCON, SiCN, Al₂O₃, TiO₂, Ta₂O₅, HfO₂, ZrO₂, or another dielectric material.

The organic layer 150 includes a planar portion 152 disposed over the planar portion 132 of the bottom reflective electrode layer 130 and a graded portion 154 disposed over the graded portion 144 of the dielectric layer 140. Here, the graded portion 154 connects to lateral ends of the planar portion 152. In some embodiments, the organic layer 150 may directly contact the bottom reflective electrode layer 130 and the dielectric layer 140. In some embodiments, the organic layer 150 may be conformal to the bottom reflective electrode layer 130 and the dielectric layer 140. In some embodiments, the organic layer 150 may extend laterally beyond the bottom reflective electrode layer 130, may extend over the top surface 124 of the PDL 120, or both. Here, the organic layer 150 includes a plurality of organic layers, namely a hole injection layer (HIL) 156, a hole transport layer (HTL) 158, an emissive layer (EML) 160, an electron transport layer (ETL) 162, and an electron injection layer (EIL) 164. However, the organic layer 150 is not particularly limited to the illustrated embodiment. For example, in another embodiment, one or more layers may be omitted from the organic layer 150. In yet another embodiment, one or more additional layers may be added to the organic layer 150. In yet another embodiment, the organic layer 150 may be inverted such that the plurality of layers are reversed.

In some embodiments, the HIL 156 may have a thickness of from about 1 nm to about 30 nm, such as from about 1 nm to about 20 nm, such as from about 5 nm to about 15 nm, or such as about 10 nm. In one exemplary embodiment, the HIL 156 may include 1,4,5,8,9,11-Hexaazatriphenylenehexacarbonitrile (HATCN).

In some embodiments, the HTL 158 may have a thickness of from about 120 nm to about 240 nm, such as from about 120 nm to about 180 nm, such as from about 140 nm to about 160 nm, such as about 150 nm, alternatively from about 140 nm to about 240 nm, such as from about 160 nm to about 230 nm, such as from about 180 nm to about 220 nm, such as from about 190 nm to about 210 nm, such as about 195 nm, or alternatively about 200 nm. In one exemplary embodiment, the HTL 158 may include N,N′-Di(1-naphthyl)-N,N′-diphenyl-(1,1′-biphenyl)-4,4′-diamine (NPB).

In some embodiments, the EML 160 may have a thickness of from about 5 nm to about 40 nm, such as from about 5 nm to about 20 nm, such as about 10 nm, alternatively from about 10 nm to about 40 nm, such as from about 10 nm to about 30 nm, or such as about 20 nm. In one exemplary embodiment, the EML 160 may include 3,3-di(9H-carbazol9-yl)biphenyl-bis[2-(2-pyridinyl-N)phenyl-C](acetylacetonato)iridium(III) (mCBP:Ir(ppy)₂(acac)).

In some embodiments, the ETL 162 may have a thickness of from about 20 nm to about 240 nm, such as from about 20 nm to about 100 nm, such as from about 40 nm to about 80 nm, such as from about 40 nm to about 60 nm, such as about 50 nm, alternatively from about 60 nm to about 80 nm, such as about 65 nm, alternatively from about 100 nm to about 240 nm, such as from about 150 nm to about 240 nm, such as from about 160 nm to about 220 nm, such as from about 170 nm to about 190 nm, such as about 180 nm, alternatively from about 180 nm to about 220 nm, such as from about 190 nm to about 210 nm, or such as about 200 nm. In one exemplary embodiment, the ETL 162 may include 2,2′,2″-(1,3,5-Benzinetriyl)-tris(1-phenyl-1-H-benzimidazole) (TPBi).

The top electrode 170 (e.g., a cathode in a standard OLED configuration) includes a planar portion 172 disposed over the planar portion 152 of the organic layer 150 and a graded portion 174 disposed over the graded portion 154 of the organic layer 150. Here, the graded portion 174 connects to opposed lateral ends of the planar portion 172. In some embodiments, the top electrode 170 may directly contact the organic layer 150. In some embodiments, the top electrode 170 may be conformal to the organic layer 150. In some embodiments, the top electrode 170 may extend laterally beyond the organic layer 150, may contact the dielectric layer 140, and/or may extend over the top surface 124 of the PDL 120. In some embodiments, the top electrode 170 may be a monolayer. In some other embodiments, the top electrode 170 may be a multi-layer stack. In some embodiments, the top electrode 170 may be formed from one or more of Al, Ag, Mg, Pt, Pd, Au, Ni, Nd, Ir, Cr, Li, LiF, Al:Ag alloys, Mg:Ag alloys, other alloys thereof, other suitable metals and their alloys, ITO, IZO, ZnO, In₂O₃, IGO, AZO, GZO, combinations thereof, and multi-layer stacks thereof. In some embodiments, the top electrode 170 may include an underlayer formed from one or more of HATCN, LiF, combinations thereof, or multi-layer stacks thereof. In some embodiments, the top electrode 170 may have a thickness of from about 5 nm to about 120 nm, such as from about 5 nm to about 50 nm, such as from about 10 nm to about 30 nm, such as about 20 nm, alternatively from about 50 nm to about 120 nm, such as from about 80 nm to about 120 nm, such as from about 90 nm to about 110 nm, or such as about 100 nm.

In one exemplary embodiment, the EL device 100 may include (from bottom to top) a bottom reflective electrode layer 130 including a multi-layer stack of alternating ITO and Ag, an HTL 158 having a thickness of about 200 nm, an EML 160 having a thickness of about 10 nm, an ETL 162 having a thickness of about 200 nm, and a top electrode 170 including Ag and having a thickness of about 20 nm. One advantage of the EL device 100 according to this embodiment is improved efficiency compared to other exemplary embodiments described herein.

In another exemplary embodiment, the EL device 100 may include (from bottom to top) a bottom reflective electrode layer 130 including a multi-layer stack of alternating ITO and Ag, an HTL 158 having a thickness of about 200 nm, an EML 160 having a thickness of about 10 nm, an ETL 162 having a thickness of about 180 nm, and a top electrode 170 including Ag and having a thickness of about 20 nm. One advantage of the EL device 100 according to this embodiment is improved color viewing compared to other exemplary embodiments described herein.

In yet another exemplary embodiment, the EL device 100 may include (from bottom to top) a bottom reflective electrode layer 130 including a multi-layer stack of alternating ITO and Ag, an HTL 158 having a thickness of about 195 nm, an EML 160 having a thickness of about 10 nm, an ETL 162 having a thickness of about 65 nm, and a top electrode 170 including ITO and having a thickness of about 100 nm. Advantages of the EL device 100 according to this embodiment are improved efficiency and reduced light absorption in the top electrode 170 compared to other exemplary embodiments described herein.

In yet another exemplary embodiment, the EL device 100 may include (from bottom to top) a bottom reflective electrode layer 130 including a multi-layer stack of alternating ITO and Ag, an HIL 156 including HATCN and having a thickness of about 10 nm, an HTL 158 including NPB and having a thickness of about 150 nm, an EML 160 including mCBP:Ir(ppy)₂(acac) and having a thickness of about 20 nm, an ETL 162 including TBPi and having a thickness of about 50 nm, and a top electrode 170 including one of a first layer including HATCN and having a thickness of about 30 nm and a second layer including ITO and having a thickness of about 80 nm ITO or a first layer including LiF and having a thickness of about 1 nm and a second layer including a Mg:Ag alloy and having a thickness of about 20 nm.

Comparing top electrodes 170 including ITO therein vs. Mg:Ag alloys therein, one advantage of an ITO top electrode is improved optical outcoupling efficiency to the filler 180a, b (η_{filler}) and resultant improvement in external optical outcoupling efficiency from the EL device 100 to air (next). In one or more embodiments, using an ITO top electrode vs. a Mg:Ag alloy top electrode, miner has been shown to improve by about 30%. In some embodiments, using an ITO top electrode has been shown to achieve η_{filler} up to about 90%. The improved efficiency of an ITO top electrode compared to a Mg:Ag alloy top electrode is due, at least in part, to lower absorption and lower surface plasmon loss for ITO compared to Mg:Ag alloys.

The filler 180a, b is disposed over the top electrode 170. In some embodiments, the filler 180a, b may directly contact the top electrode 170. As illustrated in FIG. 1C, the filler 180a is patterned such that the filler 180a is disposed in the emission region 102 without extending from the opening where the EL device 100 is formed and over the adjacent the top surface 124 of the PDL 120. In other words, the filler 180a is selectively deposited, selectively etched, or both to confine the filler 180a only to the generally concave opening formed in the PDL 120, the concave opening being defined by the bottom surface 122 and the graded sidewalls 126. Here, an exposed surface 182a of the filler 180a is planar. However, the filler 180a, b is not particularly limited to the illustrated embodiment. For example, in some other embodiments, the filler 180a may be curved. When comparing an ITO top electrode having a patterned filler to a Mg:Ag alloy top electrode having a patterned filler, next has been shown to have a resultant improvement of about 30%. However, when comparing an ITO top electrode having a non-patterned filler to a Mg:Ag alloy top electrode having a non-patterned filler, next has only shown resultant improvement of about 5%. Thus, the improvement in efficiency in more pronounced for EL devices 100 having a patterned filler.

In another embodiment, e.g., illustrated in FIG. 1D, the filler 180b is non-patterned such that the filler 180b extends over the top surface 124 of the PDL 120 outside the emission region 102. In such embodiments, the filler 180b may extend laterally beyond the top electrode 170, may contact the dielectric layer 140, or both. One advantage of the non-patterned filler 180b is that, without patterning, the filler 180a, b is easier, and thus less expensive, to fabricate. On the other hand, one advantage of the patterned filler 180a is improved external optical outcoupling efficiency from the EL device 100. This may be due, at least in part, to reduced lateral waveguided light leakage in the reduced thickness patterned filler 180a.

In some embodiments, the filler 180a, b may include one or more high refractive index materials (i.e., n≥1.8), or index-matching materials, having a similar refractive index to the emission region 102. In some embodiments, the refractive index of the filler 180a, b, may exceed the refractive index of the emission region 102 by about 0.2 or more. In one or more embodiments, the filler 180a, b may be highly transparent. For example, the filler 180a, b can include one or more metal oxides, metal nitrides, Al₂O₃, SiO₂, TiO, TaO, AlN, SiN, SiOₓNₓ, TiN, TaN, high refractive index nanoparticles, other suitable materials, and combinations thereof. Non-limiting examples of materials that can be used in the filler 180a, b include any suitable material that can be integrated into OLED fabrication, such as organic materials (e.g., N,N′-Bis(napthalen-1-yl)-N,N′-bis(phenyl)benzidine, or NPB), inorganic materials, resins, or a combination thereof. The filler 180a, b can include a composite such as a colloidal mixture where the colloids are high refractive index inorganic materials such as TiO₂.

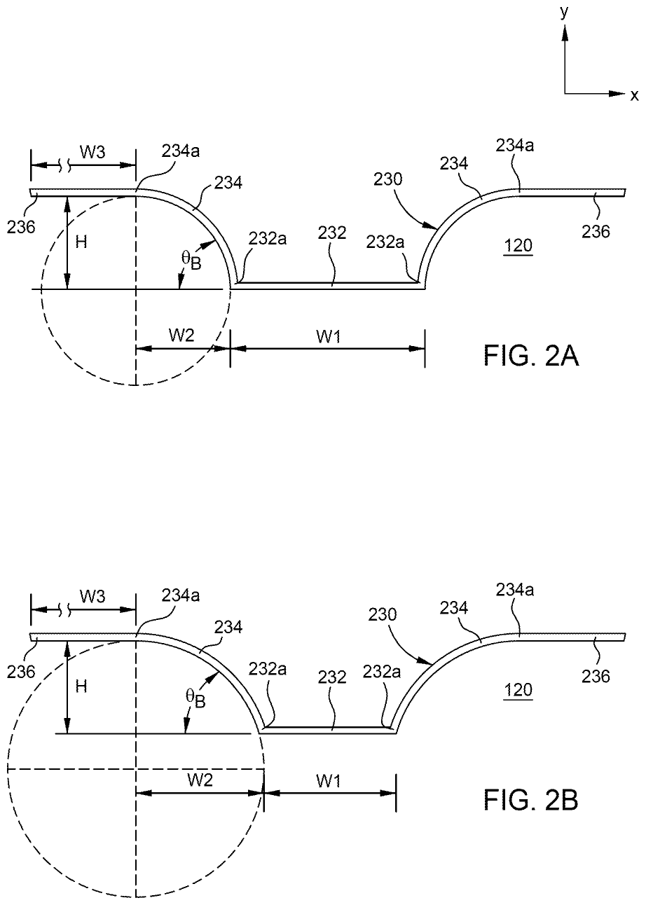

FIG. 2A is a schematic, side sectional view of a bottom reflective electrode layer 230 having a convex graded slope which may be substituted for the bottom reflective electrode layer 130 in the EL device 100 of FIGS. 1C-1D, according to an embodiment. FIG. 2B is a schematic, side sectional view of a bottom reflective electrode layer 230 having a convex graded slope which may be substituted for the bottom reflective electrode layer 130 in the EL device 100 of FIGS. 1C-1D, according to another embodiment. As illustrated in FIGS. 2A-2B, the planar portion 232 is oriented substantially along the x-axis, and the graded portion 234 connects to the opposed lateral ends 232a of the planar portion 232. The graded portion 234 is convex and forms an angle θ_{B} with the x-axis where the planar portion 232 and graded portion 234 intersect at the lateral ends 232a.

In the embodiment illustrated in FIG. 2A, the angle θ_{B} is about 90° such that the planar portion 232 and the graded portion 234 are orthogonal to each other at the location where the planar portion 232 and graded portion 234 intersect. Here, the graded portion 234 spans a range of angles relative to the x-axis from about 90° at one of the lateral ends 232a to about 0° at the graded portion end 234a. However, the angle θ_{B} is not particularly limited to the illustrated embodiment. For example, as illustrated in FIG. 2B, the angle θ_{B} may be about 30°. Here, the graded portion 234 only spans a range of angles relative to the x-axis from about 30° at one of the lateral ends 232a to about 0° at the graded portion end 234a. One advantage of the bottom reflective electrode layer 230 of FIG. 2A, relative to FIG. 2B, is that the graded portion 234 spanning a greater range of angles relative to the x-axis produces angular intensities closer to the Lambertian distribution. In yet other embodiments, the angle θ_{B} may be about 90° or less, such as from about 0° to about 90°, such as from about 0° to about 30°, such as from about 10° to about 30°, alternatively from about 30° to about 60°, or alternatively from about 60° to about 90°.

The planar portion 232 has a width W1 defined along the x-axis between the opposed lateral ends 232a. The graded portion 234 has a width W2 defined along the x-axis between one of the lateral ends 232a and the adjacent graded portion end 234a. In some embodiments, the bottom reflective electrode layer 230 includes a top portion 236 substantially parallel to the planar portion 232 having a width W3 along the x-axis. In such embodiments, the top portion 236 may extend midway between adjacent EL devices 100 (see FIG. 1B). The array 10 of EL devices 100 has a subpixel pitch defined as W1+2W2+2W3. The graded portion 234 has a height H defined along the y-axis between one of the lateral ends 232a and the graded portion end 234a. The EL device 100 has an aspect ratio defined as H/W1.

Referring to FIGS. 2A-2B, the graded portion 234 is formed along a circular arc such that the graded portion 234 has a continuously changing slope, i.e., the first derivative of the height H is linear. Here, the slope continuously decreases from the lateral end 232a to the graded portion end 234a, where the slope is defined as the steepness of the curve relative to the x-axis. However, the structure of the bottom reflective electrode layer 230 is not particularly limited to the illustrated embodiment. For example, the graded portion 234 may have any suitable non-linear profile, e.g., logarithmic, power, polynomial, exponential, sigmoid. In some other embodiments, the graded portion 234 may have a non-continuously changing slope.

Referring to FIGS. 2A-2B, the graded portion 234 is continuous with the top portion 236 such that the bottom reflective electrode layer 230 forms a smooth transition to the top portion 236 at the graded portion end 234a. The smooth transition from the graded portion 234 to the top portion 236 can improve connectivity of the structure. One advantage of the graded bank structure shown in FIGS. 2A-2B is that the graded bank structure can have a larger initial angle θ_{B} compared to a straight bank structure having comparable efficiency. That is because as the angle of the graded slope relative to the x-axis decreases along the length of the graded portion 234, efficiency is improved at smaller angles by redirecting more light into the air directly. As a result of the larger initial angle θ_{B} of the graded bank structure, the graded bank structure has a smaller width W2 relative to a straight bank structure having the same height H. This can advantageously improve fill factor of emission regions 102 at high pixel densities. Another advantage of the graded bank structure is increased efficiency compared to a straight bank structure having the same initial angle θ_{B}. This is due, at least in part, to the graded slope having decreasing angles relative to the x-axis along the length of the graded portion 234, where the lower angles redirect light directly into air, thus improving efficiency. In turn, higher efficiency improves lifetime of the device, providing same brightness at lower power, and longer one-time charge usage of mobile devices.

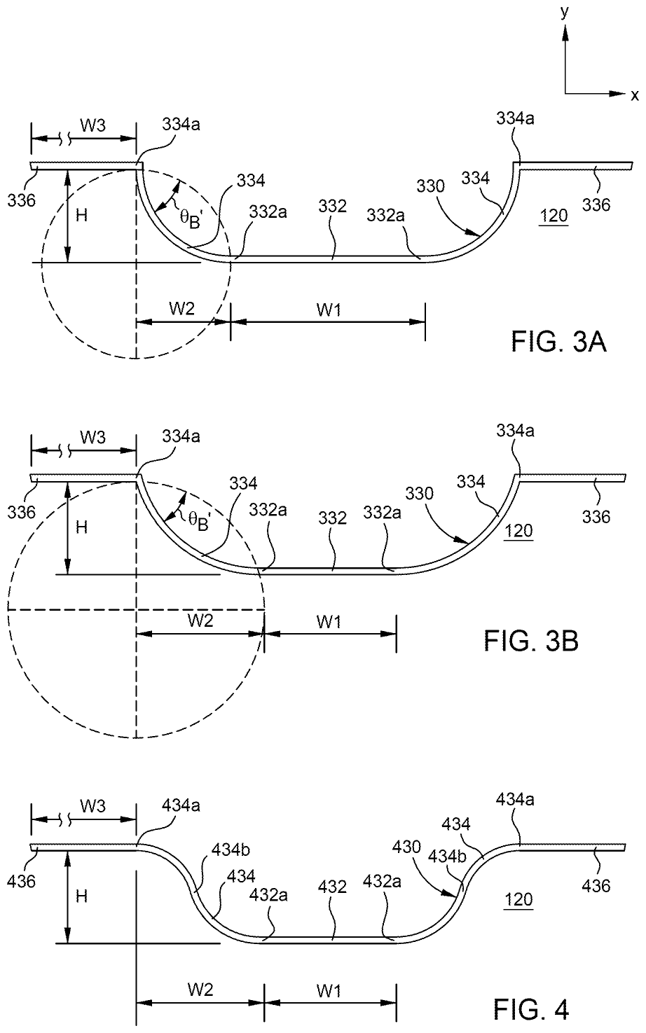

FIG. 3A is a schematic, side sectional view of a bottom reflective electrode layer 330 having a concave graded slope which may be substituted for the bottom reflective electrode layer 130 in the EL device 100 of FIGS. 1C-1D, according to an embodiment. FIG. 3B is a schematic, side sectional view of a bottom reflective electrode layer 330 having a concave graded slope which may be substituted for the bottom reflective electrode layer 130 in the EL device 100 of FIGS. 1C-1D, according to another embodiment. The bottom reflective electrode layer 330 is similar to the bottom reflective electrode layer 230 in most respects and description pertaining to the bottom reflective electrode layer 230 is incorporated herein unless otherwise noted.

As illustrated in FIGS. 3A-3B, the graded portion 334 is concave. The graded portion 334 is continuous with the planar portion 332 such that the bottom reflective electrode layer 330 forms a smooth transition at the lateral ends 332a of the planar portion 232. Moreover, the graded portion 334 is formed along an inverted circular arc such that the graded portion 334 has a continuously changing slope, i.e., the first derivative of the height H is linear. Here, the slope continuously increases from the lateral end 332a to the graded portion end 334a, where the slope is defined as the steepness of the curve relative to the x-axis. However, the structure of the bottom reflective electrode layer 330 is not particularly limited to the illustrated embodiment. For example, the graded portion 334 may have any suitable non-linear profile, e.g., logarithmic, power, polynomial, exponential, sigmoid. In some other embodiments, the graded portion 334 may have a non-continuously changing slope.

The graded portion 334 and the top portion 336 are non-continuous at the graded portion end 334a such that the graded portion 334 forms an angle θ_{B}′ with the x-axis. In the embodiment illustrated in FIG. 3A, the angle θ_{B}′ is about 90° such that the graded portion 334 and the top portion 336 are orthogonal to each other where the graded portion 334 and the top portion 336 intersect. However, the angle θ_{B}′ is not particularly limited to the illustrated embodiment. For example, as illustrated in FIG. 3B, the angle θ_{B}′ may be about 30°. In yet other embodiments, the angle θ_{B}′ may be about 90° or less, such as from about 0° to about 90°, such as from about 0° to about 30°, alternatively from about 30° to about 60°, or alternatively from about 60° to about 90°.

FIG. 4 is a schematic, side sectional view of a bottom reflective electrode layer 430 having a graded slope which may be substituted for the bottom reflective electrode layer 130 in the EL device 100 of FIGS. 1C-1D, according to another embodiment. The bottom reflective electrode layer 430 is similar to the bottom reflective electrode layers 230, 330 in most respects and description pertaining to the bottom reflective electrode layers 230, 330 is incorporated herein unless otherwise noted.

Referring to FIG. 4, the graded portion 434 of the bottom reflective electrode layer 430 has a sigmoidal profile. The graded portion 434 is continuous with the planar portion 432 at the lateral end 432a and continuous with the top portion 436 at the graded portion end 434a such that the bottom reflective electrode layer 430 forms a smooth transition at both the lateral end 432a and the graded portion end 434a. Here, the slope increases from the lateral end 432a to an inflection point 434b. Then the slope decreases from the inflection point 434b to the graded portion end 434a.

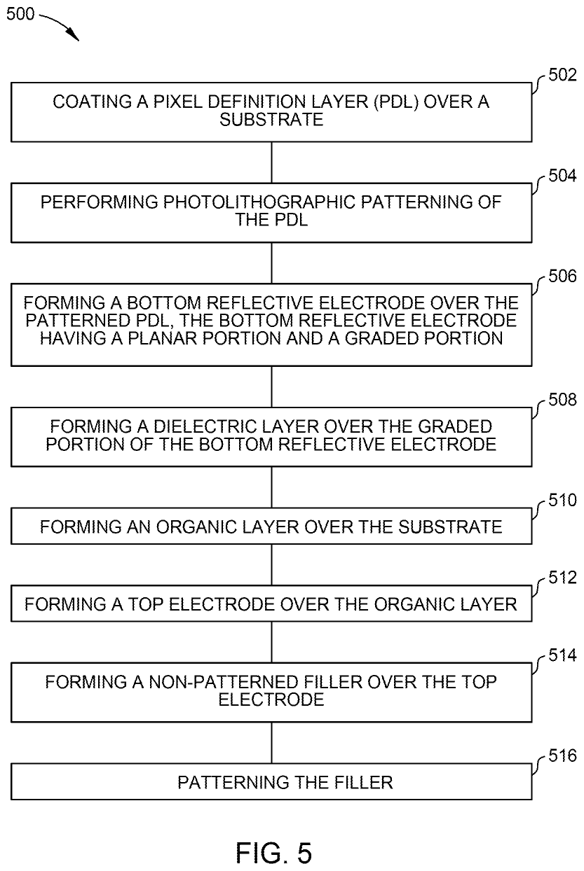

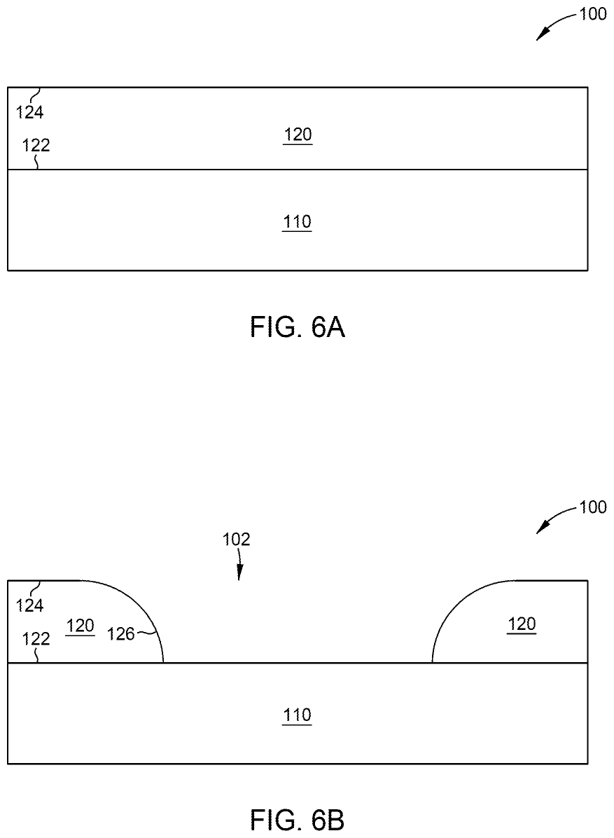

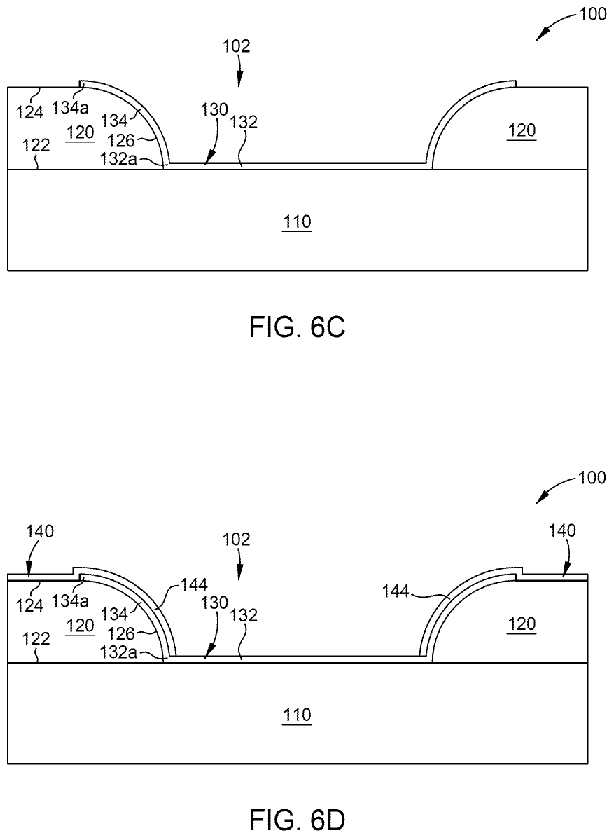

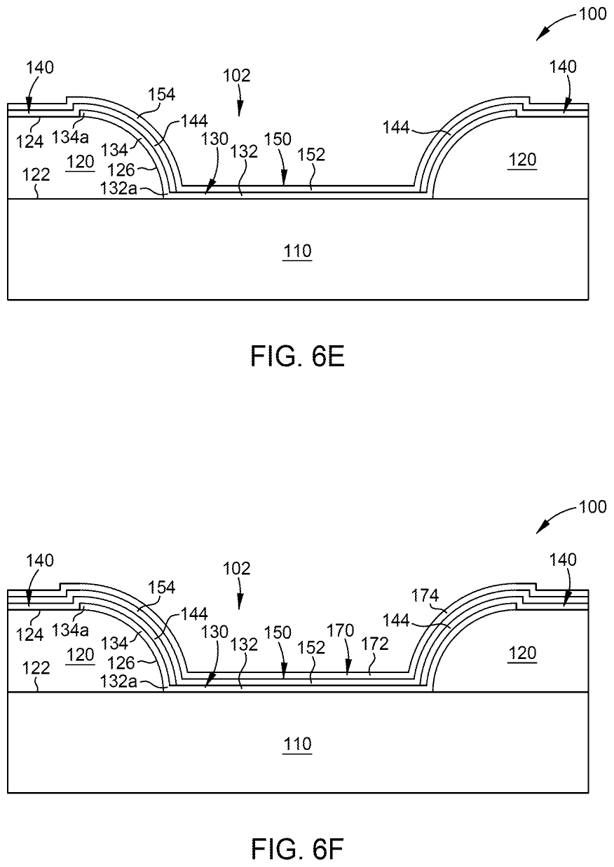

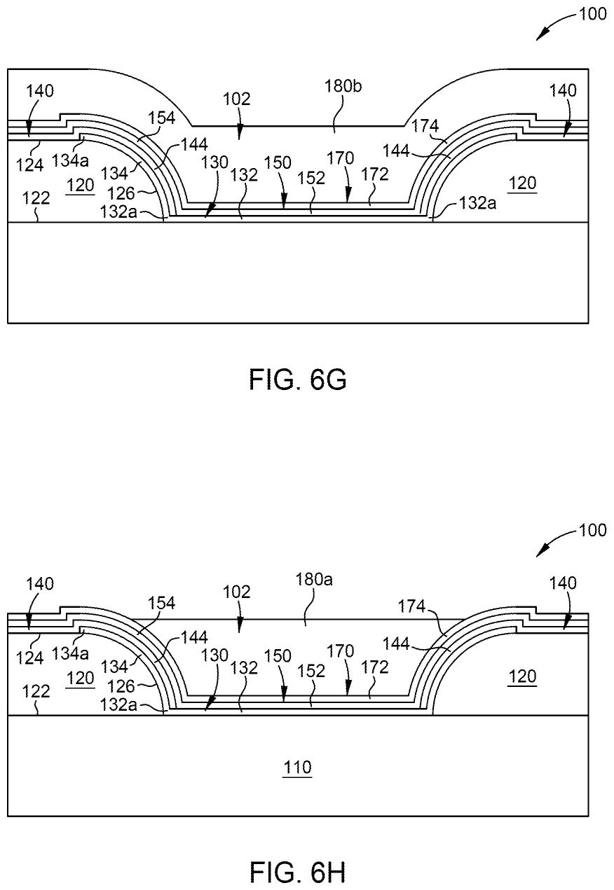

FIG. 5 is a diagram illustrating a method 500 for fabricating an EL device 100, according to an embodiment. FIGS. 6A-6H are schematic, side sectional views of an EL device 100 illustrating various aspects of the method 500 set forth in FIG. 5, according to an embodiment. Generally, the method 500 includes forming the PDL 120 having graded sidewalls 126, forming the bottom reflective electrode layer 130 having the planar portion 132 and the graded portion 134, forming the non-patterned filler 180b, and optionally patterning the non-patterned filler 180b to form the patterned filler 180a.

At activity 502, the method 500 includes coating the PDL 120 over the substrate 110 as illustrated in FIG. 6A. In some embodiments, the PDL 120 may be coated on the substrate 110 using spin-coating, spray coating, dip coating, blade coating, other suitable coating techniques, or combinations thereof. In some embodiments, the PDL 120 may have a thickness of from about 1 μm to about 4 μm, such as from about 2 μm to about 3 μm.

At activity 504, the method 500 includes performing photolithographic patterning of the PDL 120 to recess the PDL 120 from the top surface 124 thereof through to the bottom surface 122 to form the generally concave structure of the emission region 102 having the graded sidewalls 126 as illustrated in FIG. 6B. The photolithographic patterning process can include any suitable lithography process. In one embodiment, in order to form the graded sidewalls 126, the process may include gray-scale lithography using scanning gray tone exposure where dosage is increased during scanning across the EL device 100. The exposure of the PDL photoresist material may include using a gradient of exposure dosage along the PDL 120 to form a latent pattern therein. After forming the latent pattern, the photoresist material may be developed to form the patterned PDL 120 shown in FIG. 6B. The PDL photoresist material may be a positive tone photoresist such that the exposed regions of the photoresist material are removed during development.

In some other embodiments, performing the photolithographic patterning includes exposing the PDL 120 to patterned ultraviolet (UV) light through a photomask (not shown). In such embodiments, the PDL photoresist material is a negative tone photoresist. Light diffusion at edges of the photomask pattern may cause partial UV exposure forming a latent pattern in the PDL 120 corresponding to the graded sidewalls 126. With the negative tone photoresist, portions of the PDL 120 exposed to the UV light are polymerized or cross-linked, such that exposed portions are retained and unexposed portions are removed during development, forming the structure shown in FIG. 6B.

In yet other embodiments, the PDL 120 may be recessed using an etching process. In such embodiments, one of a patterned hard mask or patterned photoresist layer (not shown) is formed over the PDL 120 and used as an etch stop. Isotropic wet or dry etching may be used to etch the PDL 120. It will be appreciated that isotropic etching can result in lateral etching of the PDL 120 at edges of the patterned etch stop layer forming the graded sidewalls 126 shown in FIG. 6B.

At activity 506, the method 500 includes forming the bottom reflective electrode layer 130 over the patterned PDL 120 as illustrated in FIG. 6C. The bottom reflective electrode layer 130 includes the planar portion 132 and the graded portion 134. In some embodiments, forming the bottom reflective electrode layer 130 may include any suitable metallization technique including without limitation, physical vapor deposition (PVD), evaporation, sputtering, spin-on coating, chemical vapor deposition (CVD), low pressure CVD (LPCVD), plasma enhanced CVD (PECVD), electrolytic deposition, and epitaxy. In one or more embodiments, the bottom reflective electrode layer 130 may be deposited to conform to the graded sidewalls of the PDL 120. In one or more embodiments, forming the bottom reflective electrode layer 130 may include alternating deposition of a transparent conductive oxide layer and a metal reflective film to form a multi-layer stack thereof. In such embodiments, each layer of the multi-layer stack may be deposited using the same or different techniques. After deposition, the bottom reflective electrode layer 130 may be selectively etched to at least partially remove material of the bottom reflective electrode layer 130 from over the top surface 124 of the PDL 120 as illustrated in FIG. 6C.

At activity 508, the method 500 includes forming the dielectric layer 140 over the graded portion 134 of the bottom reflective electrode layer 130 as illustrated in FIG. 6D. In some embodiments, forming the dielectric layer 140 may include one or more techniques including PVD, CVD, PECVD, flowable CVD (FCVD), atomic layer deposition (ALD), sputtering, and spin-on coating. In one or more embodiments, the dielectric layer 140 may be deposited to conform to the planar portion 132 and the graded portion 134 of the bottom reflective electrode layer 130. After deposition, the dielectric layer 140 may be selectively etched to at least partially remove material of the dielectric layer 140 from over the planar portion 132 as illustrated in FIG. 6D.

At activity 510, the method 500 includes forming the organic layer 150 over the substrate 110, including over the planar portion 132 of the bottom reflective electrode layer 130 and over the dielectric layer 140 as illustrated in FIG. 6E. In some embodiments, forming the organic layer 150 may include one or more techniques including thermal evaporation under vacuum, ink jet printing, other suitable techniques, or combinations thereof. Here, the organic layer 150 is coated over the entire surface of the substrate 110 including over the dielectric layer 140 and underlying the top electrode 170. In some other embodiments, the organic layer 150 may be selectively deposited. In one or more embodiments, the organic layer 150 may be deposited to conform to the planar portion 132 of the bottom reflective electrode layer 130 and to the graded portion 144 of the dielectric layer 140. In one or more embodiments, forming the organic layer 150 may include sequentially depositing one or more of the HIL 156, HTL 158, EML 160, ETL 162, and EIL 164 (FIGS. 1C-1D) to form a multi-layer stack thereof. In such embodiments, each layer of the multi-layer stack may be deposited using the same or different techniques.

In some embodiments, a total thickness of the organic layer 150 may be about 300 nm or less, such as about 200 nm or less, such as about 200 nm, alternatively from about 200 nm to about 300 nm, such as from about 200 nm to about 250 nm, such as from about 220 nm to about 240 nm, or such as about 230 nm. The total thickness of the organic layer 150 is reduced from typical EL devices 100 (about 400 nm). One advantage of the reduced total thickness of the organic layer 150 is improved color uniformity due to reduced color shift across viewing angles.

At activity 512, the method 500 includes forming the top electrode 170 over the organic layer 150 as illustrated in FIG. 6F. In some embodiments, forming the top electrode 170 may include any suitable metallization technique including without limitation, PVD, evaporation, sputtering, spin-on coating, CVD, LPCVD, PECVD, electrolytic deposition, and epitaxy. In one or more embodiments, the top electrode 170 may be deposited to conform to the organic layer 150. In one or more embodiments, forming the top electrode 170 includes sequentially depositing first and second layers to form a multi-layer stack. In such embodiments, each layer of the multi-layer stack may be deposited using the same or different techniques.

At activity 514, the method 500 optionally includes forming the filler 180b over the top electrode 170 as illustrated in FIG. 6G. In some embodiments, the filler 180b may be patterned after deposition. In such embodiments, forming the filler 180b may include one or more techniques for blanket coating the filler 180b, including PVD, CVD, PECVD, FCVD, ALD, sputtering, thermal evaporation, ink jet printing, dip coating, spray coating, blade coating, and spin-on coating. In one or more embodiments, the filler 180b may be deposited to conform to the top electrode 170.

At activity 516, the method 500 optionally includes patterning the filler 180b to form the patterned filler 180a as illustrated in FIG. 6H. In some embodiments, patterning the filler 180b may include selectively etching at least some portions of the filler 180b outside the emission region 102 using a patterned hard mask or patterned photoresist layer as an etch stop. Alternatively, the filler 180a may be directly formed without a separate patterning step as described herein with respect to activity 514. In such embodiments, forming the filler 180a may include one or more patterned deposition processes including ink jet printing, vapor jet printing, or thermal evaporation using a fine metal mask.

While the foregoing is directed to examples of the present disclosure, other and further examples of the disclosure may be devised without departing from the basic scope thereof, and the scope thereof is determined by the claims that follow.

What is claimed is:

1. An electroluminescent device, comprising:
a pixel definition layer having a top surface, a bottom surface, and graded sidewalls interconnecting the top and bottom surfaces;
a bottom reflective electrode layer disposed over the pixel definition layer, the bottom reflective electrode layer including:
a planar electrode portion disposed over the bottom surface; and
a graded reflective portion disposed over the graded sidewalls, wherein the graded reflective portion has a concave profile;
an organic layer disposed over the bottom reflective electrode layer; and
a top electrode disposed over the organic layer.

2. The electroluminescent device of claim 1, further comprising a dielectric layer disposed between the graded reflective portion of the bottom reflective electrode layer and the organic layer, wherein the dielectric layer has a concave profile substantially conforming to the concave profile of the graded reflective portion.

3. The electroluminescent device of claim 1, wherein the graded sidewalls of the pixel definition layer have a concave profile, and wherein the graded reflective portion of the bottom reflective electrode layer substantially conforms to the concave profile of the graded sidewalls.

4. The electroluminescent device of claim 1, further comprising a filler disposed over the top electrode, wherein the filler is at least one of a non-patterned filler or patterned filler.

5. The electroluminescent device of claim 1, wherein the profile of the graded reflective portion is partially convex.

6. The electroluminescent device of claim 1, wherein an interconnection between the planar electrode portion and the graded reflective portion is continuous.

7. The electroluminescent device of claim 1, wherein the bottom reflective electrode layer further includes a top portion substantially parallel to the planar electrode portion.

8. The electroluminescent device of claim 7, wherein an interconnection between the graded reflective portion and the top portion is non-continuous.

9. The electroluminescent device of claim 7, wherein the graded reflective portion intersects the top portion at a first angle of about 0° to about 90°.

10. The electroluminescent device of claim 9, wherein the first angle is about 0° to about 30°.

11. A method of fabricating an electroluminescent device, comprising:
coating a pixel definition layer over a substrate, the pixel definition layer having a bottom surface facing the substrate and a top surface opposite the bottom surface;
recessing the top surface to form graded sidewalls interconnecting the top and bottom surfaces;
forming a bottom reflective electrode layer in the recess, the bottom reflective electrode layer including:
a planar electrode portion disposed over the bottom surface; and
a graded reflective portion disposed over the graded sidewalls, wherein the graded reflective portion has a non-linear profile;
forming an organic layer over the bottom reflective electrode layer; and
forming a top electrode over the organic layer.

12. The method of claim 11, further comprising forming a dielectric layer between the graded reflective portion of the bottom reflective electrode layer and the organic layer, wherein the dielectric layer has a non-linear profile substantially conforming to the non-linear profile of the graded reflective portion.

13. The method of claim 11, further comprising:
forming a non-patterned filler over the top electrode; and
patterning the non-patterned filler to form a patterned filler.

14. The method of claim 11, further comprising selectively depositing a filler over the top electrode.

15. The method of claim 11, wherein recessing the top surface to form the graded sidewalls comprises performing photolithographic patterning.

16. The method of claim 11, wherein forming the bottom reflective electrode layer in the recess comprises:
conformally depositing a transparent conductive oxide layer in the recess; and
conformally depositing a metal reflective film over the transparent conductive oxide layer.

17. A display structure, comprising:
an array of electroluminescent devices, each electroluminescent device including:
a pixel definition layer having a top surface, a bottom surface, and graded sidewalls interconnecting the top and bottom surfaces;
a bottom reflective electrode layer disposed over the pixel definition layer, the bottom reflective electrode layer including:
a planar electrode portion disposed over the bottom surface; and
a graded reflective portion disposed over the graded sidewalls, wherein the graded reflective portion has a concave profile;
an organic layer disposed over the bottom reflective electrode layer; and
a top electrode disposed over the organic layer;
a plurality of thin-film transistors forming a driving circuit array configured to drive and control the array of electroluminescent devices; and
a plurality of interconnection layers, each interconnection layer in electrical contact between an electroluminescent device and a respective thin-film transistor of the plurality of thin-film transistors.

18. The display structure of claim 17, further comprising a dielectric layer disposed between the graded reflective portion of the bottom reflective electrode layer and the organic layer, wherein the dielectric layer has a concave profile substantially conforming to the concave profile of the graded reflective portion.

19. The display structure of claim 17, wherein the graded sidewalls of the pixel definition layer have a concave profile, and wherein the graded reflective portion of the bottom reflective electrode layer substantially conforms to the concave profile of the graded sidewalls.

20. The display structure of claim 17, further comprising a filler disposed over the top electrode, wherein the filler is at least one of a non-patterned filler or patterned filler.
